(19) United States
(12) Patent Application Publication
(10) Pub. No.: US 2025/0031376 A1
(43) Pub. Date: Jan. 23, 2025

(54) SEMICONDUCTOR DEVICES AND DATA STORAGE SYSTEMS INCLUDING THE SAME

(71) Applicant: Samsung Electronics Co., Ltd., Suwon-si (KR)

(72) Inventors: Junil Lee, Suwon-si (KR); Yongjun Kim, Suwon-si (KR); Chanho Kim, Suwon-si (KR); Sangwan Nam, Suwon-si (KR); Ryoongbin Lee, Suwon-si (KR)

(21) Appl. No.: 18/582,722

(22) Filed: Feb. 21, 2024

(30) Foreign Application Priority Data
Jul. 21, 2023 (KR) 10-2023-0095010

(51) Int. Cl. H10B 43/40; G11C 16/30; H10B 41/27; H10B 41/41; H10B 43/27

(52) U.S. Cl. CPC H10B 43/40; H10B 41/27; H10B 41/41; H10B 43/27; G11C 16/30

(57) ABSTRACT

A semiconductor device may include a first semiconductor structure including a substrate, an active region in the substrate, a device isolation region defining the active region, and a capacitor structure on the device isolation region and vertically overlapping the device isolation region. The capacitor structure may include a first electrode structure extending in a first direction and including first capacitor electrodes stacked in the first direction, a second electrode structure including second capacitor electrodes stacked in the first direction, and a first insulating structure between the first electrode structure and the second electrode structure. Each of the first capacitor electrodes and the second capacitor electrodes are alternately arranged and spaced apart from each other in a second direction parallel to an upper surface of the substrate, extend in a third direction perpendicular to the first direction and the second direction, and has a plate shape.

### CROSS-REFERENCE TO RELATED APPLICATION

This application claims the benefit of priority to Korean Patent Application No. 10-2023-0095010 filed on Jul. 21, 2023, in the Korean Intellectual Property Office, and the entire contents of the above-identified application are incorporated by reference herein.

### BACKGROUND

Aspects of the present disclosure relate to semiconductor devices and to data storage systems including the same.

Semiconductor devices that are able to store high-capacity data in data storage systems that require data storage are increasingly desired. Accordingly, methods for increasing data storage capacities of semiconductor devices have been researched. For example, one method for increasing data storage capacities of semiconductor devices has been suggested in which a semiconductor device includes memory cells that are arranged three-dimensionally, instead of memory cells that are arranged two-dimensionally.

### SUMMARY

Some embodiments of the present disclosure provide semiconductor devices having improved electrical properties and reliability, which may be easily manufactured.

Some embodiments of the present disclosure provide data storage systems including semiconductor devices having improved electrical properties and reliability, which may be easily manufactured.

According to some embodiments of the present disclosure, a semiconductor device may include a first semiconductor structure including a substrate, an active region in the substrate, circuit devices on the substrate, a device isolation region defining the active region, impurity regions in the active region on first and second sides of the circuit devices, a circuit interconnection structure electrically connected to the circuit devices, and a capacitor structure on the device isolation region and vertically overlapping the device isolation region; and a second semiconductor structure including a plate layer placed on the first semiconductor structure, gate electrodes stacked and spaced apart from each other in a first direction perpendicular to an upper surface of the plate layer on the plate layer, and stacked in order, channel structures that extend in the first direction through the gate electrodes, and an upper interconnection structure electrically connected to the channel structures, wherein the capacitor structure includes a first electrode structure that extends in the first direction and including first capacitor electrodes stacked in the first direction, a second electrode structure including second capacitor electrodes stacked in the first direction, and a first insulating structure between the first electrode structure and the second electrode structure, and wherein the first capacitor electrodes and the second capacitor electrodes are alternately arranged and spaced apart from each other in a second direction that is parallel to an upper surface of the substrate, and extend in a third direction perpendicular to the first direction and the second direction, and wherein the first capacitor electrodes and the second capacitor electrodes each has a plate shape.

According to some embodiments of the present disclosure, a semiconductor device may include a substrate including the active region; circuit devices on the active region; a device isolation region defining the active region; impurity regions in the active region on both sides of the circuit devices; a first electrode structure on the device isolation region, vertically overlapping the device isolation region, and extending in a first direction that is perpendicular to an upper surface of the substrate; a second electrode structure on the device isolation region, vertically overlapping the device isolation region, and spaced apart from the first electrode structure in a second direction perpendicular to the first direction; and an insulating structure between the first electrode structure and the second electrode structure, wherein each of the first electrode structure and the second electrode structure extends in a third direction perpendicular to the first direction and the second direction and has a plate shape.

According to some embodiments of the present disclosure, a data storage system includes a semiconductor storage device including a substrate, an active region in the substrate, circuit devices on the substrate, a device isolation region defining the active region, an interconnection structure electrically connected to the circuit devices, a capacitor structure on the device isolation region and vertically overlapping the device isolation region, memory cells, and input/output pad; and a controller electrically connected to the semiconductor storage device through the input/output pad and configured to control the semiconductor storage device, wherein the capacitor structure includes a first electrode structure extending in a first direction perpendicular to an upper surface of the substrate and including first capacitor electrodes stacked in the first direction, a second electrode structure including second capacitor electrodes stacked in the first direction, and first insulating structure between the first electrode structure and the second electrode structure, and wherein the first capacitor electrodes and the second capacitor electrodes are spaced apart from each other and arranged alternately in the second direction parallel to an upper surface of the substrate, extend in the third direction perpendicular to the first direction and the second direction, and wherein each of the first capacitor electrodes and the second capacitor electrodes has a plate shape.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a block diagram illustrating a semiconductor device according to some embodiments of the present disclosure;

FIG. 2 is a circuit diagram illustrating a charge pump circuit included in a voltage generator of a semiconductor device according to some embodiments of the present disclosure;

FIG. 3 is a perspective diagram illustrating a semiconductor device according to some embodiments of the present disclosure;

FIG. 4 is a cross-sectional diagram illustrating a semiconductor device according to some embodiments of the present disclosure;

FIG. 5A is an enlarged cross-sectional diagram illustrating a portion of a semiconductor device and a cross-sectional diagram illustrating a capacitor structure according to some embodiments of the present disclosure;

FIG. 5B is a plan diagram illustrating a capacitor structure of a semiconductor device according to some embodiments of the present disclosure;

FIG. 5C is a perspective diagram illustrating a capacitor structure of a semiconductor device according to some embodiments of the present disclosure;

FIGS. 6 to 8 are enlarged cross-sectional diagrams illustrating a portion of a semiconductor device and cross-sectional diagrams illustrating a capacitor structure according to some embodiments of the present disclosure;

FIG. 9A is an enlarged cross-sectional diagram illustrating a portion of a semiconductor device and a cross-sectional diagram illustrating a capacitor structure according to some embodiments of the present disclosure;

FIG. 9B is a plan diagram illustrating a capacitor structure of a semiconductor device according to some embodiments of the present disclosure;

FIGS. 10 and 11 are enlarged cross-sectional diagrams illustrating a portion of a semiconductor device and cross-sectional diagrams illustrating a capacitor structure according to some embodiments of the present disclosure;

FIGS. 12 to 15 are cross-sectional diagrams illustrating a semiconductor device according to some embodiments of the present disclosure;

FIG. 16 is a diagram illustrating a data storage system including a semiconductor device according to some embodiments of the present disclosure;

FIG. 17 is a perspective diagram illustrating a data storage system including a semiconductor device according to some embodiments of the present disclosure; and

FIG. 18 is a cross-sectional diagram illustrating a semiconductor package according to some embodiments of the present disclosure.

### DETAILED DESCRIPTION

Hereinafter, some examples of embodiments of the present disclosure will be described as follows with reference to the accompanying drawings.

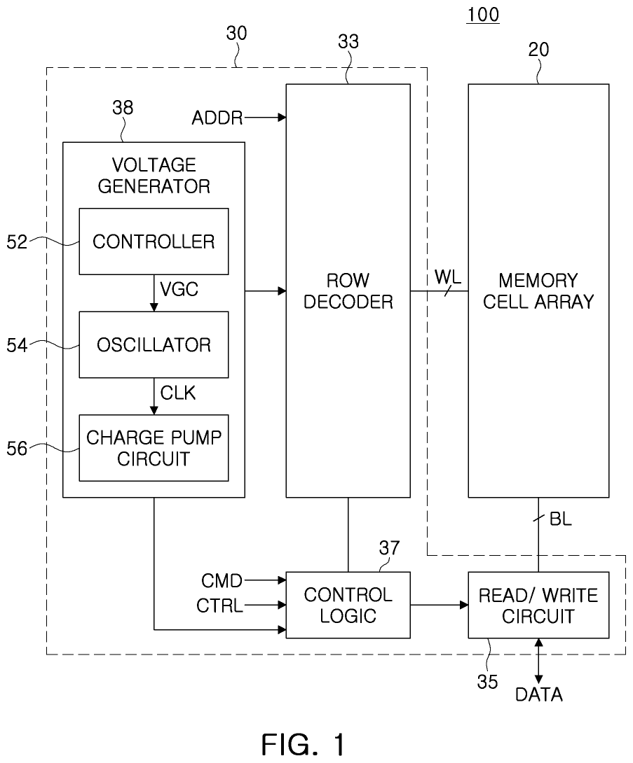

FIG. 1 is a block diagram illustrating a semiconductor device according to some embodiments of the present disclosure.

Referring to FIG. 1, a semiconductor device 100 may include a memory cell array 20 and a peripheral circuit 30. The semiconductor device 100 may be implemented as a memory device, for example, as or including a non-volatile memory such as a flash memory, and/or as or including a volatile memory such as a dynamic random access memory (DRAM) and/or a static random access memory (SRAM).

The memory cell array 20 may include a plurality of memory cells, which may be arranged into rows and columns. The plurality of memory cells may be connected to a row decoder 33 through a plurality of wordlines WL and may be connected to a read/write circuit 35 through a plurality of bitlines BL. In some embodiments, a plurality of memory cells arranged in or along the same row may be connected to the same wordline WL, and a plurality of memory cells arranged in or along the same column may be connected to the same bitline BL. In some example embodiments, a plurality of memory blocks may be included, and each memory block may include a plurality of memory cells.

The peripheral circuit 30 may receive an address ADDR, a command CMD, and a control signal CTRL from an external entity that is located externally to the semiconductor device 100 (and not shown in FIG. 1), and may transmit data DATA to and receive data DATA from the external entity and/or a device present externally of the semiconductor device 100 (and not shown in FIG. 1). The peripheral circuit 30 may include a row decoder 33, a read/write circuit 35, and a control logic 37, and the peripheral circuit 30 may include a voltage generator 38 that may generate various voltages used in operation of the semiconductor device 100. In some embodiments, the peripheral circuit 30 may further include various sub-circuits not shown in FIG. 1, such as an input/output circuit and/or an error correction circuit for correcting errors in the data DATA read from the memory cell array 20.

The control logic 37 may be connected to the row decoder 33, the voltage generator 38, and the input/output circuit. The control logic 37 may control and may be configured to control overall operations of semiconductor device 100. The control logic 37 may generate various internal control signals used in the semiconductor device 100 in response to a control signal CTRL received from the external entity discussed above. For example, the control logic 37 may adjust a voltage level provided to the wordlines WL and the bitlines BL when performing memory operations such as a program operation or an erase operation.

The row decoder 33 may select a portion of the plurality of memory cells in response to the address ADDR, and may select at least one wordline WL. The row decoder 33 may transfer voltage used in performing memory operations to the selected wordline WL.

The read/write circuit 35 may be connected to the memory cell array 20 through the bitlines BL. The read/write circuit 35 may include a write driver and/or a sense amplifier. Specifically, during a program operation, the read/write circuit 35 may operate as a write driver and may apply, to the bitlines BL, a voltage according to the data DATA to be stored in the memory cell array 20. During a read operation, the read/write circuit 35 may operate as a sense amplifier and may detect data DATA stored in the memory cell array 20.

The voltage generator 38 may include a controller 52, an oscillator 54, and a charge pump 56.

The charge pump 56 may include a plurality of charge pumps, and each of the plurality of charge pumps may include at least one switch device and at least one pumping capacitor. The output voltage of charge pump 56 may be used in operation of semiconductor device 100. For example, using the output voltage of the charge pump 56, the row decoder 33 may input a bias voltage to perform a program operation, an erase operation, and/or a read operation to the wordline WL.

The controller 52 may control operation of the oscillator 54. For example, the controller 52 may determine a frequency of the clock signal CLK which the oscillator 54 may output to the charge pump 56 based on at least one of a process, a voltage, and temperature PVT information of the semiconductor device 100 and based on a target level of the voltage which the charge pump 56 may need to output. For example, when the charge pump 56 includes a plurality of charge pumps, the selection of a number of charge pumps that are actually operating may be determined by the controller 52.

The oscillator 54 may output a clock signal CLK that turns on and turns off at least one switch device included in the charge pump 56. The clock signal CLK that is output by the oscillator 54 may be determined in response to the control signal VGC from the controller 52. For example, the oscillator 54 may determine a frequency and a swing range of the clock signal CLK differently depending on the control signal VGC transmitted by the controller 52.

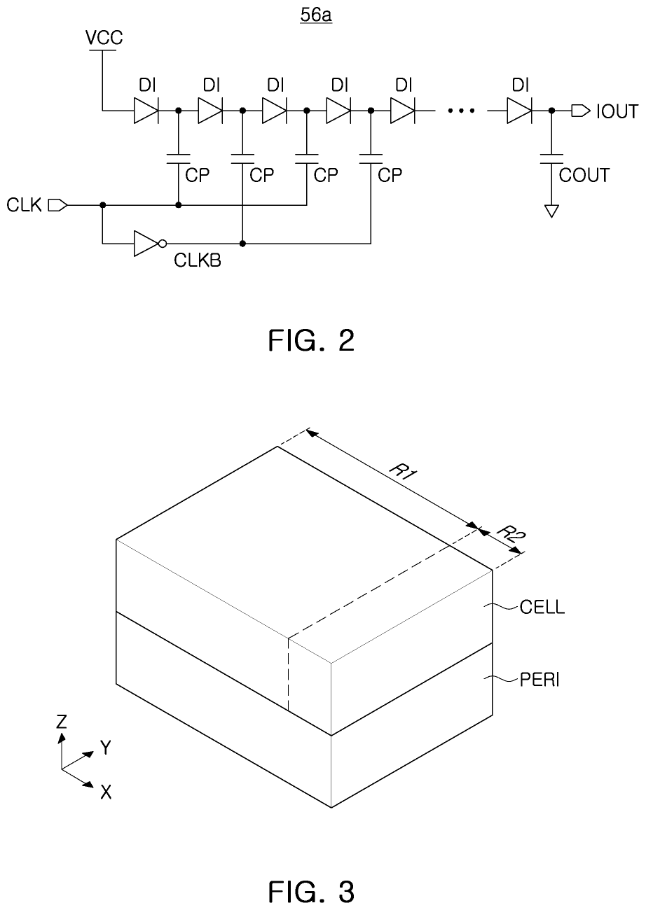

FIG. 2 is a circuit diagram illustrating a charge pump circuit included in a voltage generator of a semiconductor device according to some example embodiments.

Referring to FIG. 2, the charge pump circuit 56a may include a plurality of diodes DI, a plurality of pumping capacitors CP and an output capacitor COUT. The plurality of diodes DI may be connected to each other in series, and each of the plurality of pumping capacitors CP may be connected to a respective node between the plurality of diodes DI. The first diode may receive the power supply voltage VCC having a predetermined level, and the last diode may send the output current IOUT to the output node.

Each of the plurality of pumping capacitors CP may be charged or discharged by the clock signal CLK or the complementary clock signal CLKB which may be phase-converted to have an opposite phase to that of the clock signal CLK by an inverter INV. For example, odd-numbered pumping capacitors CP may be charged or discharged by the clock signal CLK, and even-numbered pumping capacitors CP may be charged or discharged by the complementary clock signal CLKB.

FIG. 3 is a perspective diagram illustrating a semiconductor device according to some example embodiments.

Referring to FIG. 3, the semiconductor device 10a may include a peripheral circuit structure PERI and a memory cell structure CELL. The memory cell structure CELL may be on the peripheral circuit structure PERI. The memory cell structure CELL may be a region in which the memory cell array 20 in FIG. 1 may be arranged, and the peripheral circuit structure PERI may be a region in which the peripheral circuit 30 in FIG. 1 may be arranged. In some example embodiments, alternatively, the memory cell structure CELL may be below the peripheral circuit structure PERI.

The memory cell structure CELL may include a first region R1 and a second region R2. The memory cell array 20 may be in the first region R1. The second region R2 may be configured to electrically connect memory cells of the memory cell array 20 to a peripheral circuit. The second region R2 may be arranged in at least in one direction of the first region R1. For example, the second region R2 may be arranged on at least one end of the first region R1 in the X-direction.

The plurality of pumping capacitors CP forming the charge pump circuits 56 and 56a in FIGS. 1 and 2 may be in the peripheral circuit structure PERI. For example, the plurality of pumping capacitors CP may be below the second region R2 of the memory cell structure CELL in the peripheral circuit structure PERI, but the present disclosure is not limited thereto. In some example embodiments, the plurality of pumping capacitors CP may be below the first region R1 of the memory cell structure CELL in the peripheral circuit structure PERI.

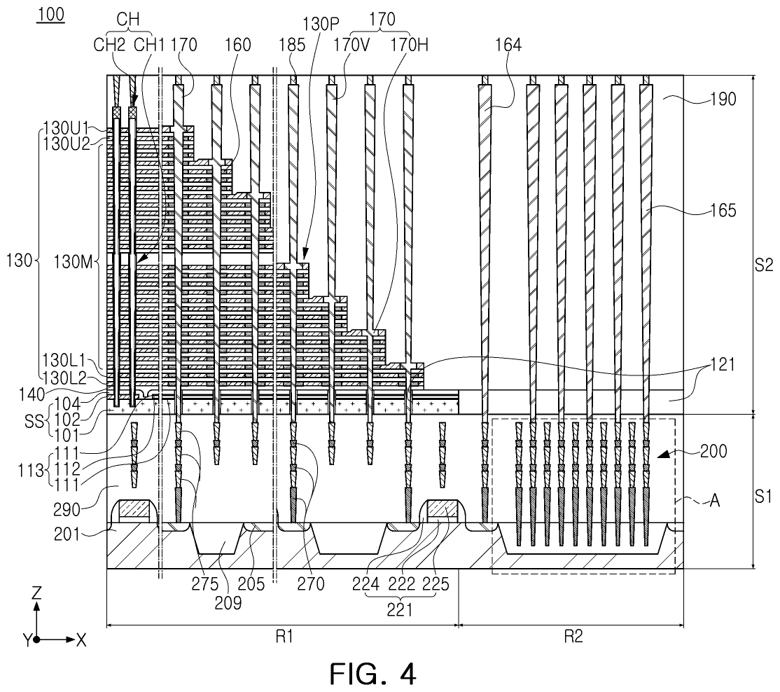

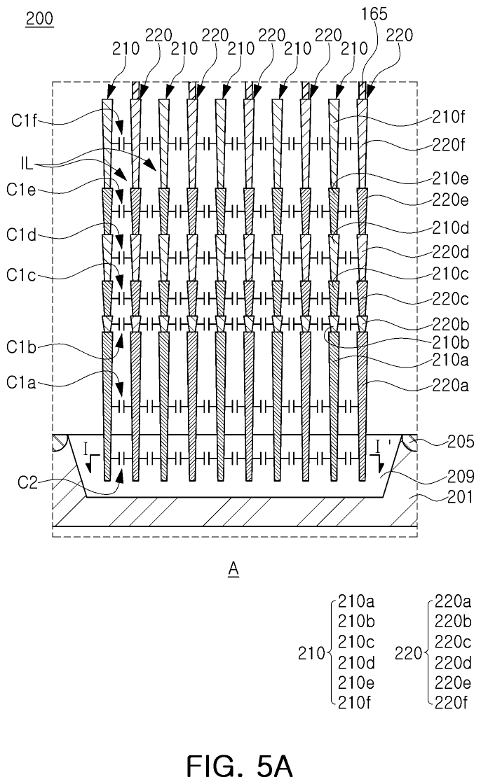

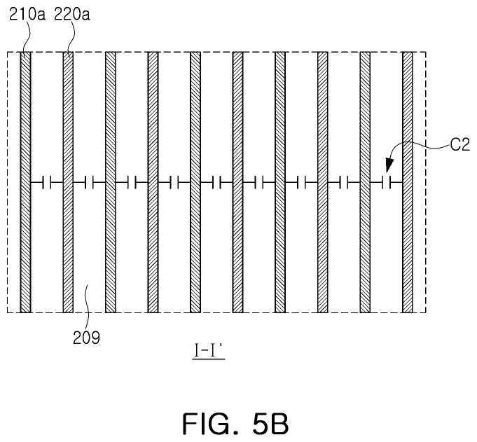

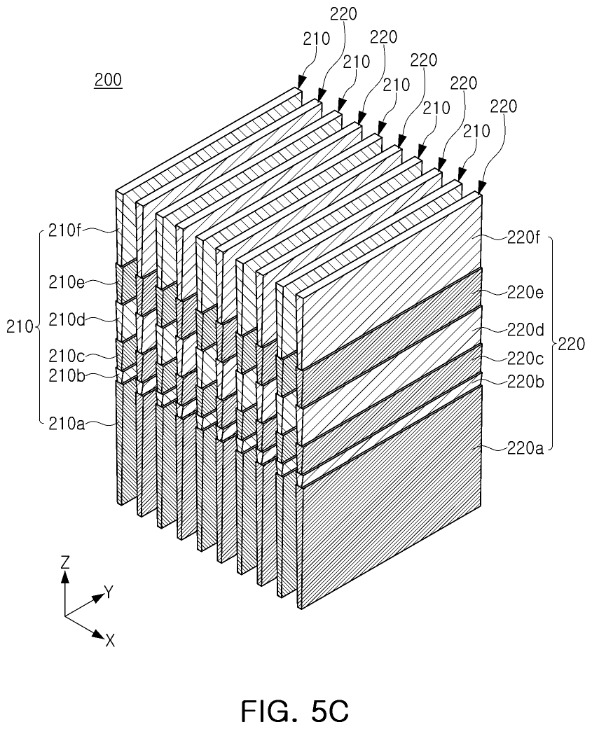

FIG. 4 is a cross-sectional diagram illustrating a semiconductor device according to some embodiments. FIG. 5A is an enlarged cross-sectional diagram illustrating a portion of a semiconductor device and a cross-sectional diagram illustrating a capacitor structure according to some embodiments, illustrating region “A” in FIG. 4. FIG. 5B is a plan diagram illustrating a capacitor structure of a semiconductor device according to some embodiments, taken along line I-I′ in FIG. 5A. FIG. 5C is a perspective diagram illustrating a capacitor structure of a semiconductor device according to some embodiments.

Referring to FIGS. 4 to 5C, the semiconductor device 100 may include a peripheral circuit structure PERI, which may be a first semiconductor structure S1 including a substrate 201, and a memory cell structure CELL, which may be a second semiconductor structure S2 including a plate layer 101.

The first semiconductor structure S1 may include a substrate 201, impurity regions 205 and device isolation regions 209 in the substrate 201, circuit devices 221 on the substrate 201, a peripheral region insulating layer 290, circuit contact plugs 270, and circuit interconnection lines 275.

The substrate 201 may have an upper surface that extends in the X-direction and the Y-direction. An active region may be defined in the substrate 201 by the device isolation regions 209. The impurity regions 205 including impurities may be in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 221 may include planar transistors. Each of the circuit devices 221 may include a circuit gate dielectric layer 222, a spacer layer 224, and a circuit gate electrode 225. The impurity regions 205 may be in the substrate 201 on first and second sides (in the X-direction) of the circuit gate electrode 225 as source/drain regions.

The peripheral region insulating layer 290 may be on the circuit device 221 on the substrate 201. The peripheral region insulating layer 290 may include a plurality of insulating layers formed in or by different processes. The peripheral region insulating layer 290 may be formed of an insulating material.

Circuit contact plugs 270 and circuit interconnection lines 275 may form circuit interconnection structures 270 and 275 which may be electrically connected to the circuit devices 221 and the impurity regions 205. The circuit interconnection structures 270 and 275 may be referred to as lower interconnection structures. The circuit contact plugs 270 may have a relatively cylindrical shape, and the circuit interconnection lines 275 may have a line shape or relatively linear shape. An electrical signal may be applied to the circuit device 221 through the circuit contact plugs 270 and the circuit interconnection lines 275. In regions not illustrated, the circuit contact plugs 270 may also be connected to a circuit gate electrode 225. The circuit interconnection lines 275 may be connected to the circuit contact plugs 270, and may be provided in a plurality of layers. The circuit contact plugs 270 and the circuit interconnection lines 275 may include a conductive material, for example, tungsten (W), copper (Cu), or aluminum (Al), and each component may further include a diffusion barrier. In some embodiments, the number of layers of the circuit contact plugs 270 and the circuit interconnection lines 275 may be varied.

The circuit interconnection structures 270 and 275 may include a capacitor structure 200. The capacitor structure 200 may include lines and contacts on the same level as a level of the other circuit contact plugs 270 and the circuit interconnection lines 275, respectively. The capacitor structure 200 may be horizontally spaced apart from other regions of the circuit interconnection structures 270 and 275. The capacitor structure 200 may be electrically connected to a portion of the circuit devices 221. The capacitor structure 200 may be in the second region R2, but the present disclosure is not limited thereto. In some example embodiments, the capacitor structure 200 may be below the first region R1 of the memory cell structure CELL, or may be below both the first and second regions R1 and R2.

The memory cell structure CELL may have first and second regions R1 and R2, and may include a source structure SS, gate electrodes 130 stacked on the source structure SS, interlayer insulating layers 140 alternately stacked with the gate electrodes 130, channel structures CH that penetrate or extend through the stack structure of the gate electrodes 130, and contact plugs 170 connected to the gate electrodes 130 and that extend vertically or in a vertical direction. The memory cell structure CELL may include a horizontal insulating layer 113 below the gate electrodes 130, substrate insulating layers 121 that penetrate or extend through the plate layer 101, studs 185 on the contact plugs 170, and a cell region insulating layer 190 that covers the gate electrodes 130.

In the memory cell structure CELL, in the first region R1, the gate electrodes 130 may be vertically stacked and may form memory cells or may be connected to the contact plugs 170. The second region R2 may be configured as an external side region of the plate layer 101.

The source structure SS may include the plate layer 101, a first horizontal conductive layer 102, and a second horizontal conductive layer 104 stacked in order. The plate layer 101 may have a plate shape and may function as at least a portion of a common source line of the semiconductor device 100. The plate layer 101 may include a conductive material, for example, a semiconductor material. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be stacked in order and may be on an upper surface of the plate layer 101 in the region in which the channel structures CH are arranged. The first horizontal conductive layer 102 may function as a portion of the common source line of the semiconductor device 100, for example, may function as a common source line together with the plate layer 101. The first horizontal conductive layer 102 may be directly connected to the channel layer in the channel structure CH. The first and second horizontal conductive layers 102 and 104 may include semiconductor materials, for example polycrystalline silicon.

The horizontal insulating layer 113 may be on the plate layer 101 at a same level as a level of the first horizontal conductive layer 102. The horizontal insulating layer 113 may include first and second horizontal insulating layers 111 and 112 that are alternately stacked on the plate layer 101. The horizontal insulating layer 113 may be layers that are remaining after a portion thereof is replaced with the first horizontal conductive layer 102 in the process of manufacturing the semiconductor device 100. The horizontal insulating layer 113 may include silicon oxide, silicon nitride, silicon carbide, or silicon oxynitride. The first horizontal insulating layers 111 and the second horizontal insulating layer 112 may include different insulating materials.

The substrate insulating layers 121 may penetrate or extend through the plate layer 101, the horizontal insulating layer 113, and the second horizontal conductive layer 104. The substrate insulating layer 121 may include an insulating material, such as silicon oxide, silicon nitride, silicon carbide, or silicon oxynitride.

The gate electrodes 130 may be stacked and vertically spaced apart from each other on the plate layer 101 and may form a stack structure together with the interlayer insulating layers 140. The stack structure may include lower and upper stack structures stacked vertically. The gate electrodes 130 may include first upper gate electrodes 130U1 and 130U2 forming string select transistors, memory gate electrodes 130M forming a plurality of memory cells, and second lower gate electrodes 130L1 and 130L2 forming a ground selection transistor. The number of memory gate electrodes 130M that form the memory cells may be determined depending on capacity of the semiconductor device 100.

The gate electrodes 130 may be vertically stacked and spaced apart from each other on the first region R1, and may extend to different lengths in the X-direction and may form stepped structures in the form of a staircase. Due to the stepped structure, a lower gate electrode 130 among the gate electrodes 130 may extend longer than a upper gate electrode 130 above the lower gate electrode 130, and the gate electrodes 130 may have contact regions 130P that ar exposed upwardly from the interlayer insulating layers 140, respectively. The gate electrodes 130 may be connected respectively to the contact plugs 170 in the contact regions 130P, which may be end regions.

The gate electrodes 130 may include a metal material, such as tungsten (W). In some embodiments, the gate electrodes 130 may include polycrystalline silicon or metal silicide material. The entirety of the gate electrodes 130 may include the same material. In some embodiments, the gate electrodes 130 may further include a diffusion barrier. For example, the diffusion barrier may include tungsten nitride (WN), tantalum nitride (TaN), titanium nitride (TiN), or a combination of two or more thereof.

The interlayer insulating layers 140 may be between the gate electrodes 130. Similarly to the gate electrodes 130, the interlayer insulating layers 140 may be spaced apart from each other in a direction perpendicular to an upper surface of the plate layer 101 and may extend in the X-direction. The interlayer insulating layers 140 may include an insulating material such as silicon oxide or silicon nitride.

Channel structures CH may penetrate or extend through the gate electrodes 130, may extend in the Z-direction, and may be connected to the plate layer 101. Each of the channel structures CH may form a memory cell string and may be spaced apart from each other while forming rows and columns on the plate layer 101. The channel structures CH may form a grid pattern in the X-Y plane or may be in a zigzag pattern in one direction. The channel structures CH may have a pillar shape and may have an inclined side surface, with a width of the channel structures in a horizontal direction decreasing in the vertical direction toward the plate layer 101.

The channel structures CH may include lower and upper channel structures CH1 and CH2 which may be vertically stacked. In the channel structures CH, lower channel structures CH1 and upper channel structures CH2 may be connected to each other, and the channel structures CH may have a bent portion due to a difference in width in the connection region. However, in some embodiments, the number of channel structures stacked in the Z-direction may be varied. Each channel structure CH may include a channel layer in a channel hole, a gate dielectric layer, a channel filling insulating layer, and a channel pad on an upper end thereof.

The contact plugs 170 may be connected to the contact regions 130P of the gate electrodes 130. The contact plugs 170 may penetrate or extend through at least a portion of the cell region insulating layer 190 and may be connected to each of the contact regions 130P of the gate electrodes 130 exposed upwardly. The contact plugs 170 may penetrate or extend through the gate electrodes 130 below the contact regions 130P, the second horizontal conductive layer 104, the horizontal insulating layer 113, and the plate layer 101, and may be connected to circuit interconnection lines 275 in the peripheral circuit structure PERI. The contact plugs 170 may be spaced apart from the gate electrodes 130 below the contact regions 130P by the contact insulating layers 160. The contact plugs 170 may be spaced apart from the plate layer 101, the horizontal insulating layer 113, and the second horizontal conductive layer 104 by the substrate insulating layers 121.

Each of the contact plugs 170 may extend horizontally in the contact region 130P. The contact plug 170 may include a vertical extension portion 170V that extends in the Z-direction and a horizontal extension portion 170H that extends horizontally from the vertical extension portion 170V and in contact with the gate electrode 130. The horizontal extension portion 170H may be arranged along a circumference of the vertical extension portion 170V, and the entire side surface may be surrounded by the gate electrode 130. The contact plugs 170 may be spaced apart from the gate electrodes 130 below the contact regions 130P, that is, the gate electrodes 130 which may not be electrically connected, by the contact insulating layers 160.

The contact plugs 170 may include at least one of a conductive material, for example, tungsten (W), copper (Cu), aluminum (Al), and alloys thereof. In some embodiments, contact plugs 170 may include a barrier layer extending along the side surface and bottom surface, or may have an air gap therein.

The contact insulating layers 160 may surround the side surfaces of each of the contact plugs 170 below the contact regions 130P. The contact insulating layers 160 may be spaced apart from each other in the Z-direction on a circumference of each contact plug 170. The contact insulating layers 160 may be at substantially the same level as a level of the gate electrodes 130, respectively. The contact insulating layers 160 may include an insulating material, for example, silicon oxide, silicon nitride, or silicon oxynitride.

Studs 185 may form a cell interconnection structure which may be electrically connected to memory cells in the memory cell structure CELL. The studs 185 may be connected to the channel structures CH and the contact plugs 170, and may be electrically connected to the channel structures CH and the gate electrodes 130. The studs 185 may include a metal, for example, tungsten (W), copper (Cu), and aluminum (Al).

The cell region insulating layer 190 may cover the stack structure of the gate electrodes 130 and the contact plugs 170. The cell region insulating layer 190 may be formed of an insulating material and may be formed of a plurality of insulating layers.

A through-plug 164 and a plurality of capacitor contacts 165 may be in the second region R2 of the memory cell region CELL, which may be an external side region of the plate layer 101. The through-plug 164 and the capacitor contacts 165 may penetrate or extend through the cell region insulating layer 190 and may extend to the peripheral circuit region PERI. The through-plug 164 and the capacitor contacts 165 may be connect the studs 185 of the memory cell region CELL to the circuit interconnection lines 275 of the peripheral circuit region PERI. The through-plug 164 and the capacitor contacts 165 may include a conductive material, for example, a metal material such as tungsten (W), copper (Cu), or aluminum (Al). The through-plug 164 and the capacitor contacts 165 may be formed in a same process of forming the contact plugs 170, may include the same material, and may have the same internal structure.

The capacitor structure 200 may be in second region R2, and may be arranged throughout the peripheral circuit region PERI and the memory cell region CELL. The capacitor structure 200 may perform a function of storing electric charges. The capacitor structure 200 may include a first electrode structure 210, a second electrode structure 220, and an insulating structure IL. The capacitor structure 200 may form the pumping capacitor CP of the charge pump circuits 56 and 56a described above with reference to FIGS. 1 to 3. The capacitor structure 200 may be on the device isolation region 209 and may vertically overlap the device isolation region 209.

The first electrode structure 210 may include first capacitor electrodes 210a, 210b, 210c, 210d, 210e, and 210f stacked in a direction perpendicular to an upper surface of the substrate 201, for example, in the Z-direction. The second electrode structure 220 may include second capacitor electrodes 220a, 220b, 220c, 220d, 220c, and 220f stacked in the Z-direction. The first capacitor electrodes 210a, 210b, 210c, 210d, 210e, and 210f and the second capacitor electrodes 220a, 220b, 220c, 220d, 220c, and 220f may be alternately arranged and spaced apart from each other in the X-direction parallel to the upper surface of the substrate 201. Since the first capacitor electrodes 210a, 210b, 210c, 210d, 210e, and 210f and the second capacitor electrodes 220a, 220b, 220c, 220d, 220c, and 220f may be formed together in the process of forming the circuit contact plugs 270 and the circuit interconnection lines 275, the capacitor electrodes may be at substantially the same level as a level of the circuit interconnection structures 270 and 275. Since the first electrode structure 210 and the second electrode structure 220 are on the device isolation region 209, the electrode structures may not be electrically connected to the circuit devices 221.

The capacitor structure 200 may be on the substrate 201. The first electrode structure 210 and the second electrode structure 220 may be on the device isolation region 209 and may penetrate through at least a portion of the device isolation region 209. A lowermost portion of each of the first electrode structure 210 and the second electrode structure 220 may be on a level lower than a level of the lowermost portion of the circuit interconnection structures 270 and 275, but the present disclosure is not limited thereto. The first electrode structure 210 and the second electrode structure 220 may have different potentials. In some embodiments, the first electrode structure 210 and the second electrode structure 220 may receive an electrical signal through a wire connected to at least a portion of the first capacitor electrodes 210a, 210b, 210c, 210d, 210e, and 210f and the second capacitor electrodes 220a, 220b, 220c, 220d, 220e, and 220f. In some embodiments, the capacitor contact 165 may apply bias to the second capacitor electrodes 220a, 220b, 220c, 220d, 220e, and 220f. Accordingly, a potential difference may be formed between the first capacitor electrodes 210a, 210b, 210c, 210d, 210e, and 210f and the second capacitor electrodes 220a, 220b, 220c, 220d, 220e, and 220f. The amount of electric charge which the capacitor structure 200 may store may be proportional to a product of the potential difference and a capacitance of the capacitor structure 200. The capacitance may be proportional to a product of a dielectric constant of insulating structure IL and an area in which the first capacitor electrodes 210a, 210b, 210c, 210d, 210e, and 210f and second capacitor electrodes 220a, 220b, 220c, 220d, 220e, and 220f on the left and right sides of the insulating structure IL oppose each other, and may be inversely proportional to a distance between the first capacitor electrodes 210a, 210b, 210c, 210d, 210e, and 210f and the second capacitor electrodes 220a, 220b, 220c, 220d, 220e, and 220f on the left and right sides of the insulating structure IL.

As illustrated in FIG. 5c, the first capacitor electrodes 210a, 210b, 210c, 210d, 210e, and 210f and the second capacitor electrodes 220a, 220b, 220c, 220d, 220e, and 220f may have a plate shape that extends in Y-direction and Z-direction, but the present disclosure is not limited thereto. In some embodiments, at least a portion of the first capacitor electrodes 210a, 210b, 210c, 210d, 210e, and 210f and the second capacitor electrodes 220a, 220b, 220c, 220d, 220e, and 220f may have a line shape or a pillar shape.

The first capacitor electrodes 210a, 210b, 210c, 210d, 210e, and 210f and the second capacitor electrodes 220a, 220b, 220c, 220d, 220e, and 220f may be provided in a plate shape, such that, as compared to being provided in a pillar shape, the area of the first capacitor electrodes 210a, 210b, 210c, 210d, 210e, and 210f and the second capacitor electrodes 220a, 220b, 220c, 220d, 220e, and 220f may increase, and capacitance of capacitor structure 200 may be increased. Also, each of the first capacitor electrodes 210a, 210b, 210c, 210d, 210e, and 210f and the second capacitor electrodes 220a, 220b, 220c, 220d, 220e, and 220f may penetrate or extend through at least a portion of the device isolation region 209, and may extend in the Z-direction, accordingly, capacitance of the capacitor structure 200 may be improved. As depths of the device isolation region 209, the first capacitor electrodes 210a, 210b, 210c, 210d, 210e, and 210f and the second capacitor electrodes 220a, 220b, 220c, 220d, 220e, and 220f increase, the capacitance of the capacitor structure 200 may be improved.

In some embodiments, the number of layers forming the first capacitor electrodes 210a, 210b, 210c, 210d, 210e, and 210f and the number of layers forming the second capacitor electrodes 220a, 220b, 220c, 220d, 220e, and 220f may be varied.

The first electrode structure 210 and the second electrode structure 220 may include a metal material, for example, tungsten (W), copper (Cu), and aluminum (Al). The first capacitor electrodes 210a, 210b, 210c, 210d, 210e, and 210f and the second capacitor electrodes 220a, 220b, 220c, 220d, 220e, and 220f may include the same materials, but the present disclosure is not limited thereto. In some embodiments, the first capacitor electrodes 210a, 210b, 210c, 210d, 210e, and 210f may include materials different from those of the second capacitor electrodes 220a, 220b, 220c, 220d, 220e, and 220f. For example, the first capacitor electrodes 210a, 210b, 210c, 210d, 210e, and 210f may include a metal material, and the second capacitor electrodes 220a, 220b, 220c, 220d, 220e, and 220f may include a semiconductor material. The insulating structure IL may be an insulating layer including an insulating material, for example, silicon oxide, silicon nitride, silicon carbide, or silicon oxynitride. In some embodiments, the insulating structure IL may include a plurality of insulating layers. The dielectric constant of the insulating structure IL may increase toward the substrate 201 or the device isolation region 209.

As illustrated in FIG. 5b, the first capacitor electrodes 210a, 210b, 210c, 210d, 210e, and 210f and the second capacitor electrodes 220a, 220b, 220c, 220d, 220e, and 220f on the same level as a level of the first capacitor electrodes 210a, 210b, 210c, 210d, 210e, and 210f and the second capacitor electrodes 220a, 220b, 220c, 220d, 220e, and 220f, and the insulating structure IL therebetween may form a metal-insulator-metal capacitor (MIM), capacitances thereof may be C1a, C1b, C1c, C1d, C1e, and C1f, respectively, and values may be different, but the present disclosure is not limited thereto. Also, the lowermost first capacitor electrode 210a and the lowermost second capacitor electrode 220a, and the device isolation region 209 therebetween may form a MIM capacitor and capacitance thereof may be C2.

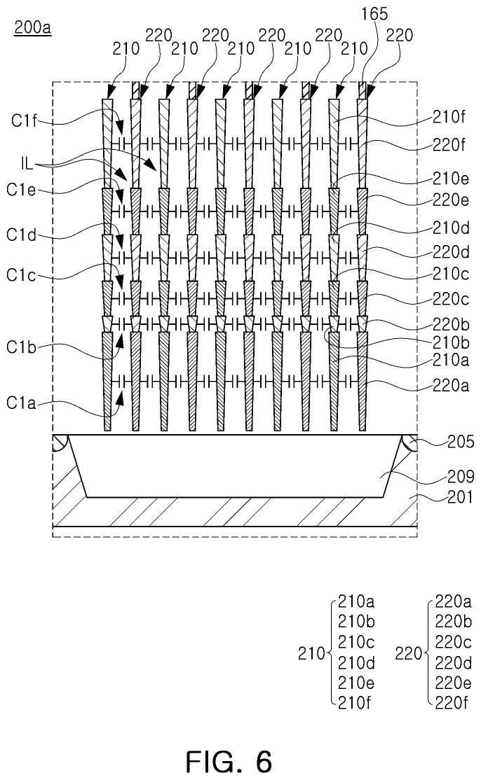

FIG. 6 is an enlarged cross-sectional diagram illustrating a portion of a semiconductor device and a cross-sectional diagram illustrating a capacitor structure according to some embodiments, illustrating a region corresponding to FIG. 5A.

Referring to FIG. 6, in a capacitor structure 200a, a lowermost end of each of the first capacitor electrodes 210a, 210b, 210c, 210d, 210e, and 210f and the second capacitor electrodes 220a, 220b, 220c, 220d, 220e, and 220f may be on a level higher than a level of the uppermost surface of the substrate 201. In some embodiments, the first capacitor electrodes 210a, 210b, 210c, 210d, 210e, and 210f and the second capacitor electrodes 220a, 220b, 220c, 220d, 220e, and 220f may be spaced apart from an upper surface of the device isolation region 209 on the device isolation region 209. In a portion of a process of manufacturing the semiconductor device 100a, the first capacitor electrodes 210a, 210b, 210c, 210d, 210e, and 210f and the second capacitor electrodes 220a, 220b, 220c, 220d, 220e, and 220f may be formed together in the process of forming the circuit interconnection structures 270 and 275 without another process of penetrating the device isolation region 209, such that process costs and difficulty may be reduced.

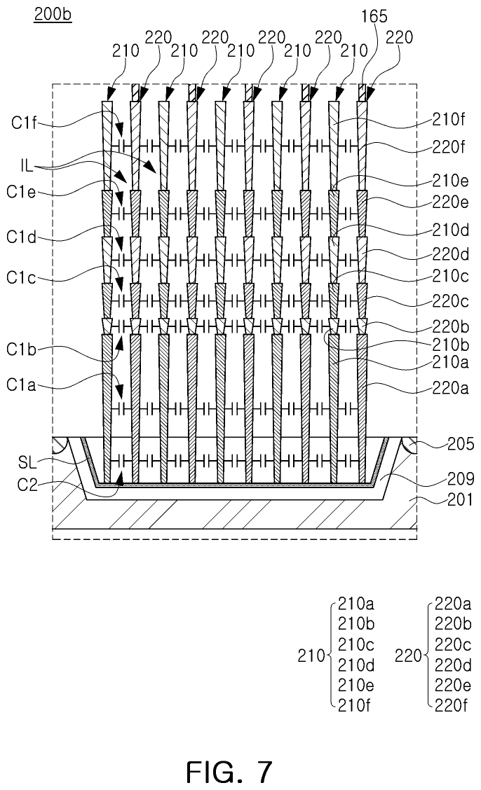

FIG. 7 is an enlarged cross-sectional diagram illustrating a portion of a semiconductor device and a cross-sectional diagram illustrating a capacitor structure according to some embodiments, illustrating a region corresponding to FIG. 5A.

Referring to FIG. 7, a first semiconductor structure S1 may further include a stopper layer SL on a portion of the surface of the substrate 201 along a surface of the substrate 201 in the device isolation region 209. In some embodiments, at least a portion of first capacitor electrodes 210a, 210b, 210c, 210d, 210e, and 210f and second capacitor electrodes 220a, 220b, 220c, 220d, 220e, and 220f may be in contact with the stopper layer SL, but the present disclosure is not limited thereto. In some embodiments, the first capacitor electrodes 210a, 210b, 210c, 210d, 210e, and 210f and the second capacitor electrodes 220a, 220b, 220c, 220d, 220e, and 220f may be spaced apart from the stopper layer SL. The stopper layer SL may prevent the first capacitor electrodes 210a, 210b, 210c, 210d, 210e, and 210f and the second capacitor electrodes 220a, 220b, 220c, 220d, 220e, and 220f from being in contact with the substrate 201. The stopper layer SL may include at least one of insulating materials, such as SiN, SiON, SiCN, SiOC, SiOCN, and SiO. The stopper layer SL and the first insulating structure IL1 may include other materials, but the present disclosure is not limited thereto.

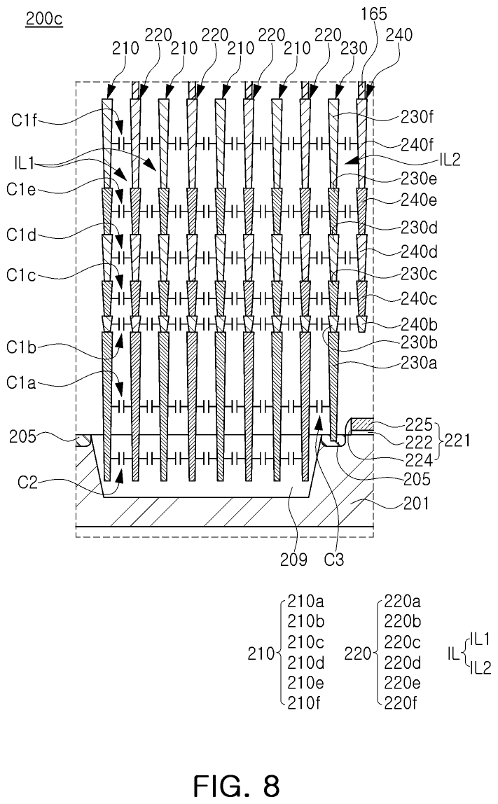

FIG. 8 is an enlarged cross-sectional diagram illustrating a portion of a semiconductor device and a cross-sectional diagram illustrating a capacitor structure according to some embodiments, illustrating a region corresponding to FIG. 5A.

Referring to FIG. 8, the semiconductor device may further include a third electrode structure 230 and a fourth electrode structure 240 on impurity regions 205 and circuit devices 221. The third electrode structure 230 may extend in the Y-direction and may be stacked in the Z-direction on the impurity regions 205, and the fourth electrode structure 240 may extend in the Y-direction and may be stacked in the Z-direction on the circuit devices 221. The second insulating structure IL may be between the third electrode structure 230 and the fourth electrode structure 240. The second insulating structure IL2 may represent the insulating structure IL on the impurity regions 205 and the circuit devices 221, but may be formed in substantially the same process of forming the first insulating structure IL1, such that the second insulating structure IL2 may include the same material as that of the first insulating structure IL1. The third electrode structure 230, the fourth electrode structure 240, and the second insulating structure IL2 between the third electrode structure 230 and the fourth electrode structure 240 may form a MIM capacitor, and capacitances may be C1b, C1c, C1d, C1e, and C1f, the values may have different values, but the present disclosure is not limited thereto. Also, the second electrode structure 220, the third electrode structure 230, and the insulating structure IL between the second electrode structure 220 and the third electrode structure 230 may form a MIM capacitor, capacitances may be C3, C1b, C1c, C1d, and C1e, C1f, and the values may have different values, but the present disclosure is not limited thereto.

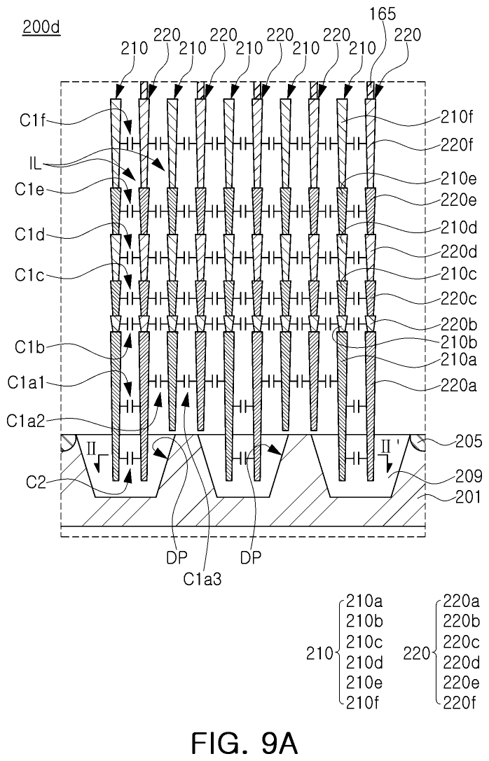

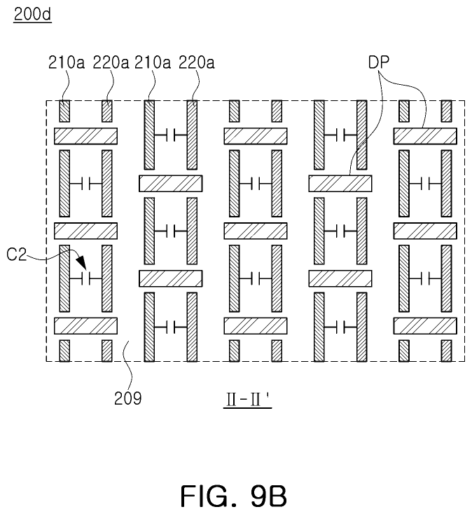

FIG. 9A is an enlarged cross-sectional diagram illustrating a portion of a semiconductor device and a cross-sectional diagram illustrating a capacitor structure according to some embodiments, illustrating a region corresponding to FIG. 5A. FIG. 9B is a plan diagram illustrating a capacitor structure of a semiconductor device according to some embodiments, taken along line II-II′ in FIG. 9A.

Referring to FIGS. 9A and 9B, the first semiconductor structure S1 may be spaced apart from each other in the X-direction and the Y-direction, and may further include dummy patterns DP in a region vertically overlapping the capacitor structure 200D. The dummy patterns DP may be defined by the device isolation region 209. In some embodiments, the device isolation region 209 may be between the dummy patterns DP. Circuit devices 221 may not be on the dummy pattern DP, but the present disclosure is not limited thereto. When the circuit devices 221 are on the dummy patterns DP, the circuit devices 221 may not be connected to the first capacitor electrodes 210a, 210b, 210c, 210d, 210e, and 210f and the second capacitor electrodes 220a, 220b, 220c, 220d, 220e, and 220f, and may be referred to as dummy circuit devices. The dummy patterns DP may prevent dishing in which the device isolation region 209 becomes convex downwardly when a subsequent flattening process is performed. The dummy patterns DP may be spaced apart in an island-type, but the present disclosure is not limited thereto. At least a portion of the first electrode structure 210 and the second electrode structure 220 may vertically overlap the dummy patterns DP. In some embodiments, the first electrode structure 210 and the second electrode structure 220 vertically overlapping the dummy patterns DP may be spaced apart from the dummy patterns DP, and the first electrode structure 210 and the second electrode structure 220 not vertically overlapping the dummy patterns DP may be on the device isolation region 209 between the dummy patterns DP. Since the first electrode structure 210 and the second electrode structure 220 may penetrate or extend through at least a portion of the device isolation region 209, the area in which the first capacitor electrodes 210a, 210b, 210c, 210d, 210e, and 210f and the second capacitor electrodes 220a, 220b, 220c, 220d, 220e, and 220f included in the capacitor structure 200D oppose each other may increase such that capacitance may be increased. The device isolation region 209 between the lowermost first capacitor electrode 210a and the lowermost second capacitor electrode 220a may form a MIM capacitor, and a capacitance may be C2. In some embodiments, the MIM capacitor formed by the lowermost first capacitor electrode 210a, the lowermost second capacitor electrode 210B, and the insulating structure IL may have capacitances of C1a1, C1a2, and C1a3. The capacitance may be varied depending on the area, the length, and the material of the lowermost first capacitor electrode 210a and the lowermost second capacitor electrode 210B.

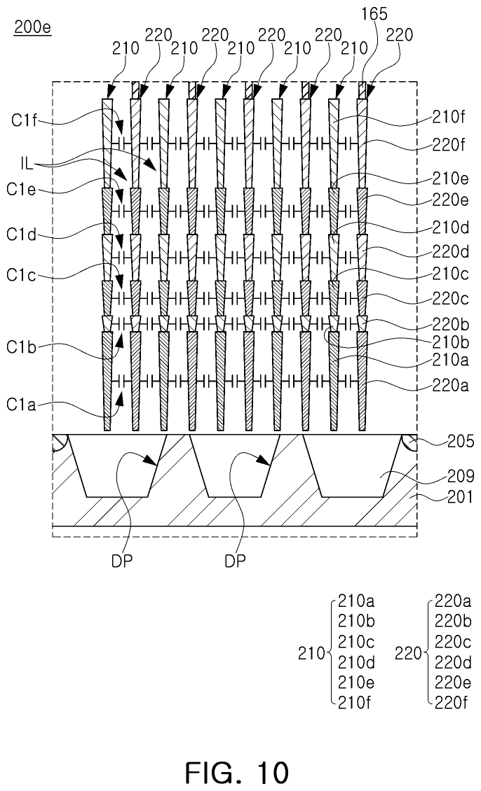

FIG. 10 is an enlarged cross-sectional diagram illustrating a portion of a semiconductor device and a cross-sectional diagram illustrating a capacitor structure according to some embodiments, illustrating a region corresponding to FIG. 5A.

Referring to FIG. 10, in contrast to the capacitor structure 200D in FIG. 9A, the first capacitor electrodes 210a, 210b, 210c, 210d, 210e, and 210f and the second capacitor electrodes 220a, 220b, 220c, 220d, 220e, and 220f may be at a level higher than an upper surface of a device isolation region 209 and may be spaced apart from the dummy patterns DP. The descriptions described with reference to FIGS. 9A and 9B may be further applied to the description of the dummy patterns DP.

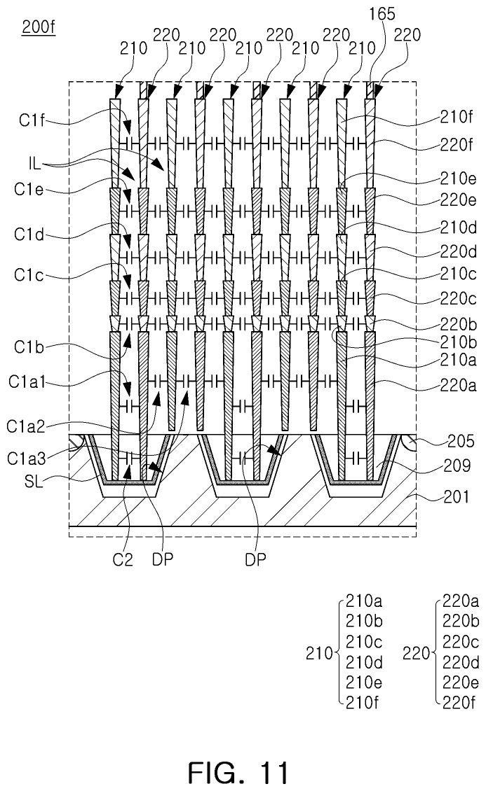

FIG. 11 is an enlarged cross-sectional diagram illustrating a portion of a semiconductor device and a cross-sectional diagram illustrating a capacitor structure according to some embodiments, illustrating a region corresponding to FIG. 5A.

Referring to FIG. 11, the semiconductor device may further include dummy patterns DP spaced apart from each other and between circuit devices 221 in the X-direction and the Y-direction. Also, a stopper layer SL on a portion of the surface of substrate 201 and the surface of dummy pattern DP along the surface of the substrate 201 and the dummy pattern DP in the device isolation region 209 may be further included. As for the description of dummy patterns DP, the descriptions described with reference to FIGS. 9A and 9B may be applied. After forming a stopper layer SL to cover the dummy patterns DP, the device isolation region 209 may be formed to cover a region between the dummy patterns DP and to cover the stopper layer SL, and the upper surface of the dummy patterns DP may be exposed through a planarization process. Accordingly, the stopper layer SL may not cover the upper surface of the dummy patterns DP. The description of the stopper layer SL described with reference to FIG. 7 may be further applied.

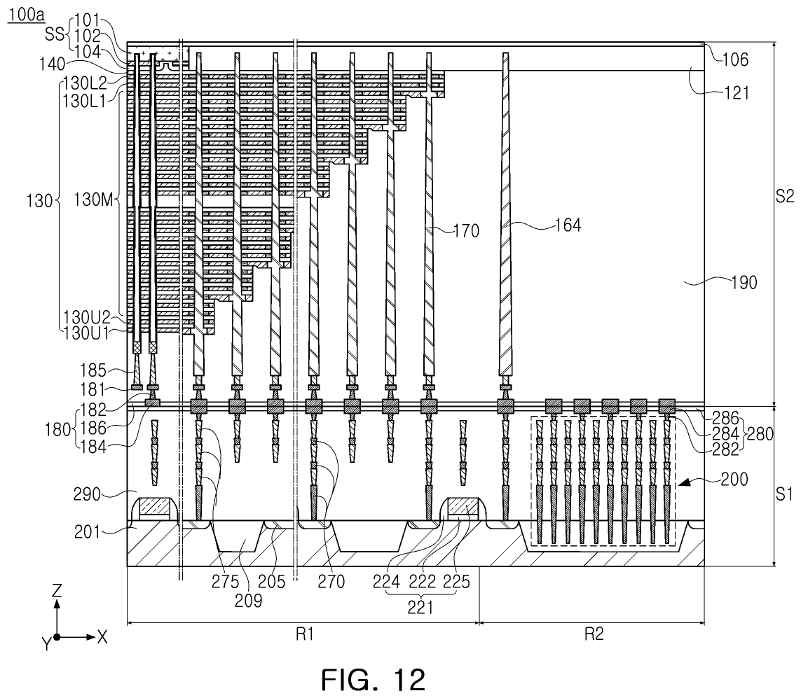

FIG. 12 is a cross-sectional diagram illustrating a semiconductor device according to some embodiments.

Referring to FIG. 12, the semiconductor device 100a may include a first semiconductor structure S1 and a second semiconductor structure S2 that are bonded to each other using a wafer bonding method.

The description of the peripheral circuit structure PERI in FIG. 4 may be applied to the first semiconductor structure S1. However, the first semiconductor structure S1 may further include first bonding vias 282, first bonding pads 284, and a first bonding insulating layer 286, which together may be a first bonding structure 280. The first bonding via 282 may be connected to the circuit interconnection structures 270 and 275. The first bonding pad 284 may be connected to the first bonding via 282. The first bonding via 282 and the first bonding pad 284 may include a conductive material, for example, tungsten (W), copper (Cu), aluminum (Al), or the like, and each component may further include a diffusion barrier. The first bonding insulating layer 286 may also function as a diffusion barrier of the first bonding pad 284 and may include at least one of SiCN, SiO, SiN, SiOC, SiON and/or SiOCN. The first bonding insulating layer 286 may have a thickness that is smaller than that of the first bonding pad 284, but the present disclosure is not limited thereto.

The first bonding pads 284 may be connected to second bonding pads 184 of the second semiconductor structure S2. The first bonding structure 280 may be bonded or connected to a second bonding structure 180 by being in direct contact with the same through hybrid bonding. For example, each first bonding pad 284 may be in contact with and bonded to a respective second bonding pad 184 through copper (Cu)-copper (Cu) bonding (copper-to-copper bonding), and the first bonding insulating layer 286 may be in contact with and bonded to a second bonding insulating layer 186 by dielectric-to-dielectric bonding. The first bonding structure 280, together with the second bonding structure 180, may provide an electrical connection path according to bonding between the first semiconductor structure S1 and the second semiconductor structure S2. A portion of the first bonding pads 284 may not be connected to the lower circuit interconnection lines 275 and may be provided only for bonding. The first bonding insulating layer 286 may be arranged around the first bonding pads 284.

The description of the memory cell structure CELL in FIG. 4 may be applied to the second semiconductor structure S2. The second semiconductor structure S2 may further include the second bonding structure 180, which may include second bonding vias 182, the second bonding pads 184, and the second bonding insulating layer 186. The second semiconductor structure S2 may further include cell interconnection lines 181, and a passivation layer 106 covering the upper surface of the plate layer 101.

The second bonding vias 182 and the second bonding pads 184 may be below studs 185. In some embodiments, the cell interconnection lines 181 may be further between the second bonding vias 182 and the studs 185. The second bonding vias 182 may connect the studs 185 to the second bonding pads 184, and the second bonding pads 184 may be bonded to the first bonding pads 184 of the first semiconductor structure S1. The second bonding insulating layer 186 may be connected to the first bonding insulating layer 286 of the first semiconductor structure S1 by bonding. The second bonding vias 182 and the second bonding pads 184 may include a conductive material, for example, copper (Cu). The second bonding insulating layer 186 may include, for example, at least one of SiO, SiN, SiCN, SiOC, SiON, and SiOCN.

Cell interconnection lines 181 may form an upper interconnection structure electrically connected to memory cells in the memory cell region CELL. The cell interconnection lines 181 may be connected to contact plugs 170 and a through-plug 164, and may be electrically connected to the gate electrodes 130 and the channel structures CH. In some embodiments, the number of interconnection lines included in the upper interconnection structure may be varied. The cell interconnection lines 181 may include metal, for example, tungsten (W), copper (Cu), aluminum (Al), or the like.

The passivation layer 106 may be on an upper surface of the plate layer 101 and may protect the semiconductor device 100B. The passivation layer 106 may include at least one of an insulating material, for example, silicon oxide, silicon nitride, and silicon carbide, and may include a plurality of insulating layers in some embodiments. In some embodiments, upper ends of contact plugs 170 may be in the substrate insulating layer 121.

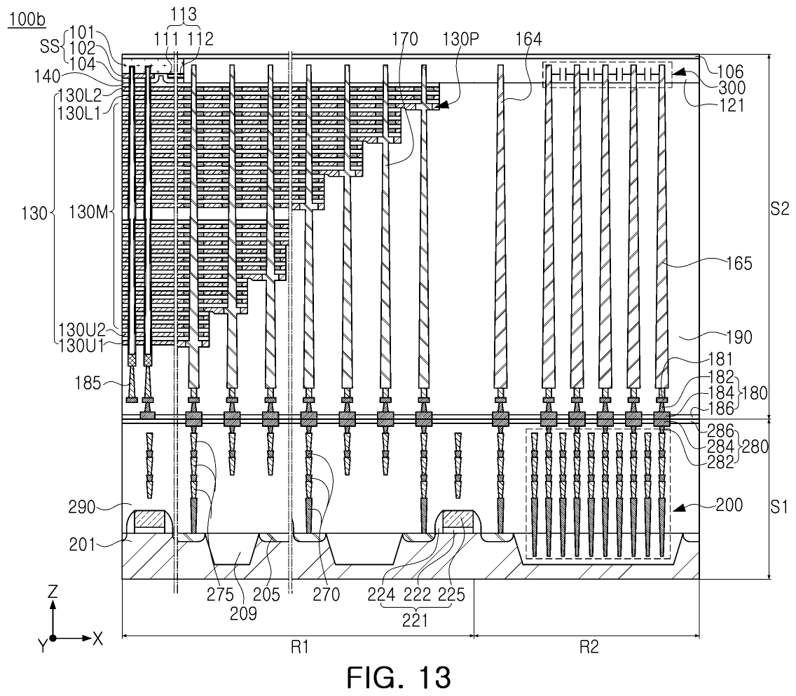

FIG. 13 is an enlarged cross-sectional diagram illustrating a portion of a semiconductor device and a cross-sectional diagram illustrating a capacitor structure according to some embodiments.

Referring to FIG. 13, the semiconductor device 100b may further include a second capacitor structure 300 in the semiconductor device 100a in FIG. 12. The second capacitor structure 300 may include capacitor contacts 165 and a substrate insulating layer 121. The second capacitor structure 300 may be in second region R2 on an external side of plate layer 101. The capacitor contacts 165 may penetrate or extend through a portion of the substrate insulating layer 121. In the substrate insulating layer 121, capacitor contacts 165 adjacent to each other may have different potentials. In some embodiments, based on the capacitor contacts 165 having potentials different from those of the substrate insulating layer 121 between the capacitor contacts 165, the semiconductor device 100b having improved capacitance may be provided.

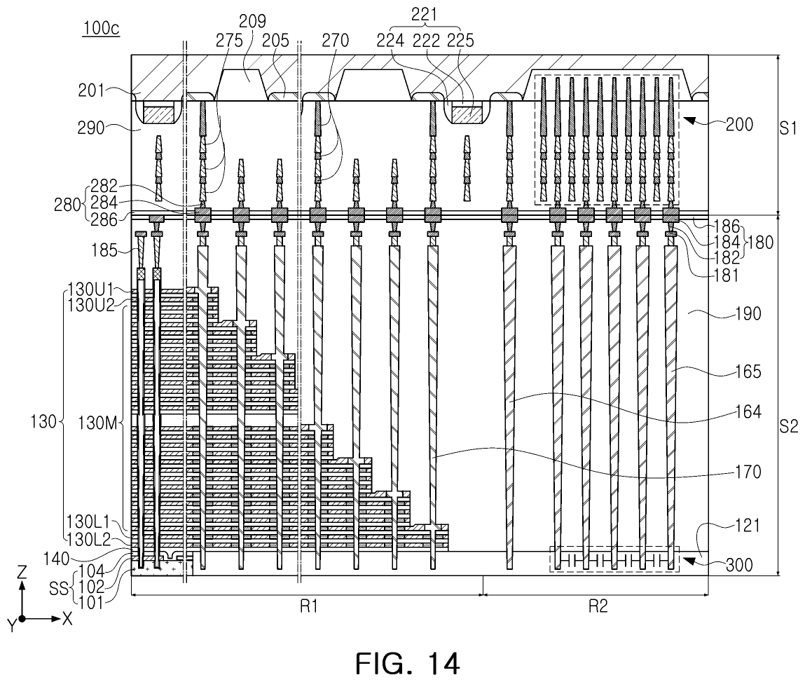

FIG. 14 is a cross-sectional diagram illustrating a semiconductor device according to some embodiments.

Referring to FIG. 14, the semiconductor device 100c may include a first semiconductor structure S1 and a second semiconductor structure S2 bonded to each other by wafer bonding. The second semiconductor structure S2 may include a memory semiconductor chip, and the first semiconductor structure S1 may include a logic semiconductor chip, but the present disclosure is not limited thereto.

The second semiconductor structure S2 may be in a lower portion, and the first semiconductor structure S1 may be in a mirror shape on the second semiconductor structure S2. The description of the peripheral circuit structure PERI described with reference to FIG. 4 may be applied to the first semiconductor structure S1. However, the first semiconductor structure S1 may further include first bonding vias 282, first bonding pads 284, and first bonding insulating layer 286, which may be a first bonding structure 280. The description of the memory cell structure CELL described with reference to FIG. 4 may be applied to the second semiconductor structure S2. The second semiconductor structure S2 may further include second bonding vias 182, second bonding pads 184, and second bonding insulating layer 186, which may be a second bonding structure 180. The first bonding pads 284 may be connected on the upper surface of the second bonding pads 184 of the second semiconductor structure S2. The first bonding structure 280 may be bonded or connected to the second bonding structure 180 by being in direct contact with the second bonding structure 180 through hybrid bonding. The descriptions overlapping the content described above in FIG. 12 will not be provided herein in the interest of brevity.

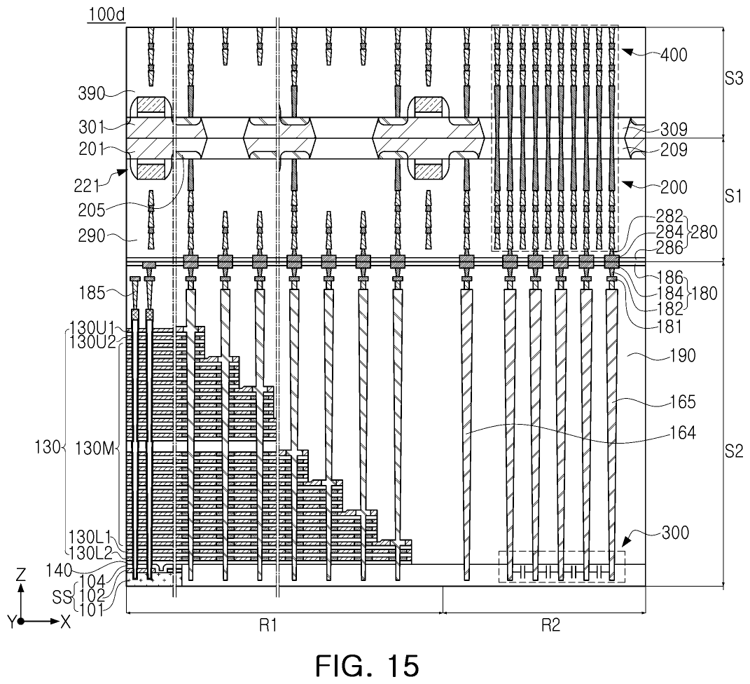

FIG. 15 is a cross-sectional diagram illustrating a semiconductor device according to some embodiments.

Referring to FIG. 15, in a semiconductor device 100C of FIG. 14, the third semiconductor structure S3 may be on the first semiconductor structure S1. The description of the peripheral circuit structure PERI described with reference to FIG. 4 may be applied to the third semiconductor structure S3. The third semiconductor structure S3 may be symmetrical to the first semiconductor structure S1, and the description of the first semiconductor structure S1 may be applied thereto. The description of the substrate 201, the device isolation region 209, and the peripheral region insulating layer 290 of the first semiconductor structure S1 may be applied to the substrate 301, the device isolation region 309, and the peripheral region insulating layer 390 of the third semiconductor structure S3. The third semiconductor structure S3 may be on the device isolation region 309 and may further include a third capacitor structure 400 vertically overlapping the device isolation region 309. On the lower surface of the third semiconductor structure S3, a portion of the substrate 301 and the device isolation region 309 may be removed through a planarization process, such that a portion of the third capacitor structure 400 may be exposed. On the upper surface of the first semiconductor structure S1, the substrate 201 and the device isolation region 209 may be partially removed through the planarization process, such that a portion of the first capacitor structure 200 may be exposed. The first capacitor structure 200 of the first semiconductor structure S1 may be connected and bonded to the third capacitor structure 400 of the third semiconductor structure S3. The substrate 201 of the first semiconductor structure S1 and the substrate of the third semiconductor structure S3 may be bonded to each other by being in direct contact with each other. The device isolation region 209 of the first semiconductor structure S1 and the device isolation region 309 of the third semiconductor structure S3 may be connected to each other by being in direct contact with each other. The first semiconductor structure S1 may include the first capacitor structure 200 on the device isolation region 209, the second semiconductor structure S2 may include a second capacitor structure 300 on the substrate insulating layer 121, and the third semiconductor structure S3 may include a third capacitor structure 400 on the device isolation region 309, such that capacitance in the semiconductor device 100D may be maximized, and integration density and electrical properties of the semiconductor device 100D may be improved.

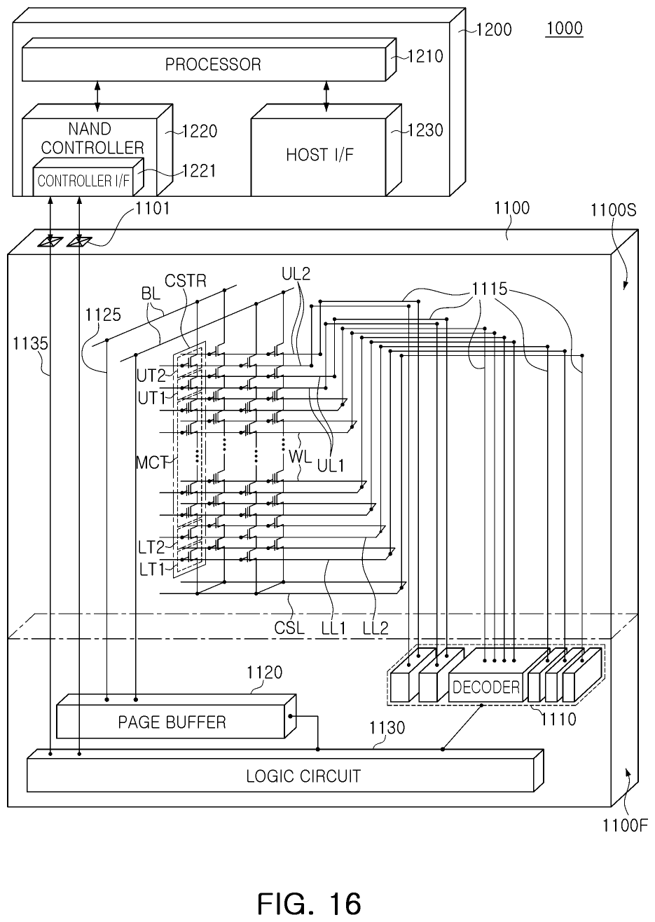

FIG. 16 is a diagram illustrating a data storage system including a semiconductor device according to some embodiments.

Referring to FIG. 16, a data storage system 1000 may include a semiconductor device 1100 and a controller 1200 that is electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device in the aforementioned embodiments described with reference to FIGS. 1 to 15. The semiconductor device 1100 may include a first structure 1100F and a second structure 1100S on the first structure 1100F. In some embodiments, the first structure 1100F may be on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR between the bitline BL and the common source line CSL.

In the second structure 1100S, each of the memory cell strings CSTR may include lower transistors LT1 and LT2 adjacent to the common source line CSL, upper transistors UT1 and UT2 adjacent to the bitline BL, and a plurality of memory cell transistors MCT between the lower transistors LT1 and LT2 and the upper transistors UT1 and UT2. The number of lower transistors LT1 and LT2 and the number of upper transistors UT1 and UT2 may be varied in different embodiments.

In some embodiments, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In some embodiments, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 that extends from the first structure 1100F to the second structure 1100S.

The controller 1200 may include a processor 1210, a NAND controller 1220, and a host interface 1230. In some embodiments, the data storage system 1000 may include a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 may include a controller interface 1221 configured to process communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

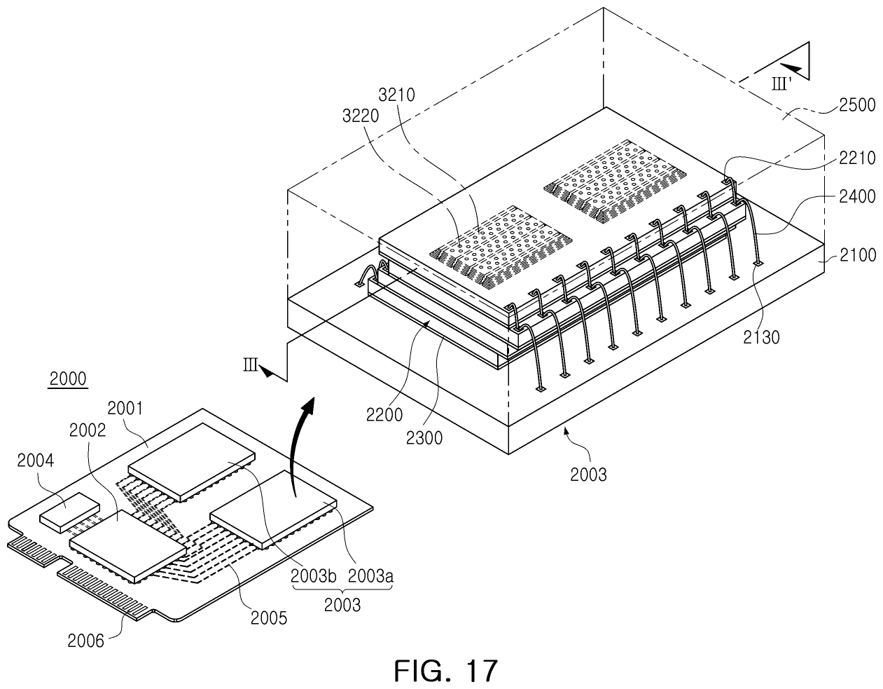

FIG. 17 is a perspective diagram illustrating a data storage system including a semiconductor device according to some embodiments.

Referring to FIG. 17 a data storage system 2000 in some embodiments may include a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 may include a connector 2006 including a plurality of pins coupled to an external host (not shown). The number and arrangement of the plurality of pins in the connector 2006 may be varied depending on a communication interface between the data storage system 2000 and the external host. some embodiments, the data storage system 2000 may communicate with an external host according to one of interfaces from among universal serial bus (USB), peripheral component interconnect express (PCI-Express), serial advanced technology attachment (SATA), M-Phy for universal flash storage (UFS). In some embodiments, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which may be a data storage space, and the external host. The DRAM 2004 included in the data storage system 2000 may operate as a cache memory, and may provide a space for temporarily storing data in a control operation for the semiconductor package 2003. When the data storage system 2000 may include the DRAM 2004, the controller 2002 may further include a DRAM controller for controlling the DRAM 2004 in addition to the NAND controller for controlling the semiconductor package 2003.

The semiconductor package 2003 may include first and second semiconductor packages 2003a and 2003b which may be spaced apart from each other. Each of the first and second semiconductor packages 2003a and 2003b may be configured as a semiconductor package including a plurality of semiconductor chips 2200. Each of the first and second semiconductor packages 2003a and 2003b may include a package substrate 2100, semiconductor chips 2200 on the package substrate 2100, adhesive layers 2300 on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 may include an input/output pad 2210. The input/output pad 2210 may correspond to the input/output pad 1101 in FIG. 16. Each of the semiconductor chips 2200 may include gate stack structures 3210 and channel structures 3220. Each of the semiconductor chips 2200 may include the semiconductor device in the aforementioned embodiments described with reference to FIGS. 1 to 15.

In some embodiments, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In some embodiments, in each of the first and second semiconductor packages 2003a and 2003b, the semiconductor chips 2200 may be electrically connected to each other by a connection structure including a through-electrode (TSV) instead of the connection structure 2400 of a bonding wire method.

In some embodiments, the controller 2002 and the semiconductor chips 2200 may be included in a single package. In some embodiment, the controller 2002 and the semiconductor chips 2200 may be mounted on an interposer substrate different from the main board 2001, and the controller 2002 and the semiconductor chips 2200 may be connected to each other by interconnection formed on the interposer substrate.

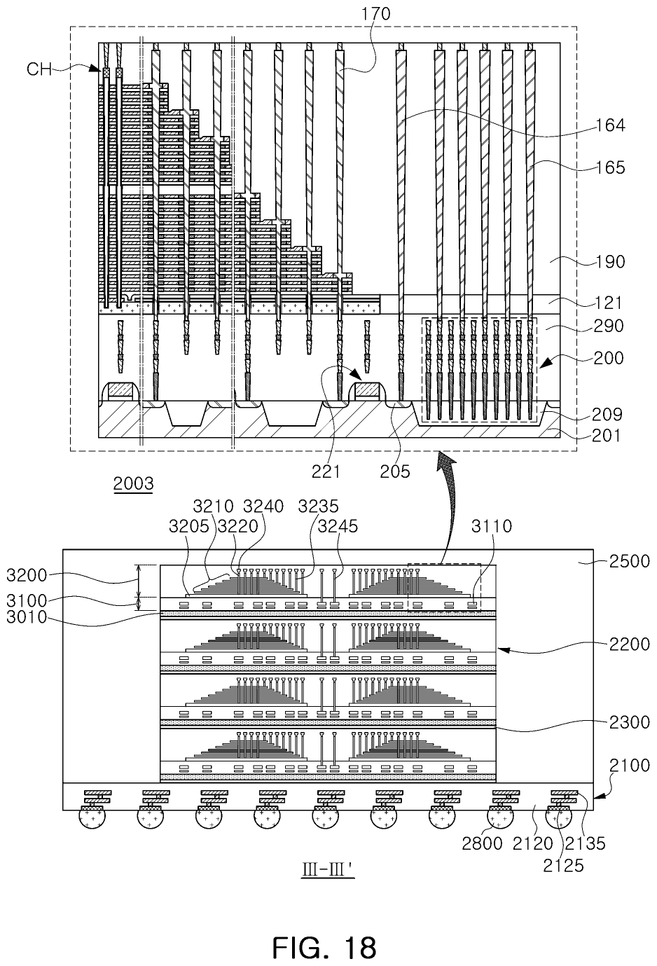

FIG. 18 is a cross-sectional diagram illustrating a semiconductor package according to some embodiments, illustrating an example of the semiconductor package 2003 in FIG. 17 taken along line III-III′.

Referring to FIG. 18, in the semiconductor package 2003, the package substrate 2100 may be implemented as a printed circuit substrate. The package substrate 2100 may include may include a package substrate body portion 2120, package upper pads 2130 on an upper surface of the package substrate body portion 2120 (see FIG. 17), lower pads 2125 on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the interconnection patterns 2005 of the main the substrate 2001 of the data storage system 2000 through the conductive connection portions 2800 as illustrated in FIG. 17.

Each of the semiconductor chips 2200 may include a semiconductor substrate 3010 and a first structure 3100 and a second structure 3200 stacked in order on the semiconductor substrate 3010. The first structure 3100 may include a peripheral circuit region including peripheral interconnections 3110. The second structure 3200 may include a common source line 3205, a gate stack structure 3210 on the common source line 3205, channel structures 3220 penetrating or extending through the gate stack structure 3210, bitlines 3240 electrically connected to the channel structures 3220, and contact plugs 3235 electrically connected to the wordlines WL (see FIG. 16) of the gate stack structure 3210. As described in the aforementioned embodiments described with reference to FIGS. 1 to 15, each of the semiconductor chips 2200 may include the capacitor structure 200 on the device isolation region 209 vertically overlapping the device isolation region 209.

Each of the semiconductor chips 2200 may include a through-interconnection 3245 electrically connected to the peripheral interconnections 3110 of the first structure 3100 and extending into the second structure 3200. The through-interconnection 3245 may be on an external side of the gate stack structure 3210 and may further be arranged to penetrate or extend through the gate stack structure 3210. Each of the semiconductor chips 2200 may further include an input/output pad 2210 (see FIG. 17) electrically connected to the peripheral interconnections 3110 of the first structure 3100.

According to the aforementioned examples of embodiments, by providing a capacitor structure on the device isolation region and vertically overlapping the device isolation region, a semiconductor device having improved electrical properties and reliability and a data storage system including the same may be provided.

While some examples of embodiments have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a substrate, an active region in the substrate, circuit devices on the substrate, a device isolation region defining the active region, impurity regions in the active region on first and second sides of the circuit devices, a circuit interconnection structure electrically connected to the circuit devices, and a capacitor structure on the device isolation region and vertically overlapping the device isolation region; and
a second semiconductor structure including a plate layer placed on the first semiconductor structure, gate electrodes stacked and spaced apart from each other in a first direction perpendicular to an upper surface of the plate layer on the plate layer, and stacked in order, channel structures that extend in the first direction through the gate electrodes, and an upper interconnection structure electrically connected to the channel structures,
wherein the capacitor structure includes:
a first electrode structure that extends in the first direction and including first capacitor electrodes stacked in the first direction, a second electrode structure including second capacitor electrodes stacked in the first direction, and a first insulating structure between the first electrode structure and the second electrode structure,
wherein the first capacitor electrodes and the second capacitor electrodes are alternately arranged and spaced apart from each other in a second direction that is parallel to an upper surface of the substrate, and extend in a third direction perpendicular to the first direction and the second direction, and
wherein the first capacitor electrodes and the second capacitor electrodes each has a plate shape.

2. The semiconductor device of claim 1,
wherein each of the first electrode structure and the second electrode structure includes the first capacitor electrodes and the second capacitor electrodes stacked in the first direction, and
wherein at least a portion of the first capacitor electrodes and the second capacitor electrodes extend at least into a portion of the device isolation region.

3. The semiconductor device of claim 2,
wherein the first semiconductor structure further includes a stopper layer on a portion of a surface of the substrate along the surface of the substrate in the device isolation region, and
wherein at least a portion of the first capacitor electrodes and the second capacitor electrodes are in contact with the stopper layer.

4. The semiconductor device of claim 3,
wherein the stopper layer includes an insulating material, and
wherein the stopper layer and the first insulating structure include different materials.

5. The semiconductor device of claim 2, wherein the first capacitor electrodes include a metal material, and wherein the second capacitor electrodes include a semiconductor material.

6. The semiconductor device of claim 2, wherein a lowermost portion of each of the first electrode structure and the second electrode structure is on a level lower than a level of a lowermost portion of the circuit interconnection structure.

7. The semiconductor device of claim 1, wherein the first semiconductor structure further includes dummy patterns spaced apart from each other in the second direction and the third direction and in a region that vertically overlaps the capacitor structure.

8. The semiconductor device of claim 7, further comprising:
a stopper layer on a portion of a surface of the substrate and a surface of the dummy pattern along a surface of the substrate and a surface of the dummy pattern in the device isolation region.

9. The semiconductor device of claim 7,
wherein the device isolation region is between the dummy patterns, and
wherein at least a portion of the first electrode structure and the second electrode structure vertically overlap the dummy patterns.

10. The semiconductor device of claim 7, wherein at least a portion of the first electrode structure and the second electrode structure that vertically overlap the device isolation region extend at least into a portion of the device isolation region.

11. The semiconductor device of claim 1,
wherein the first insulating structure includes a plurality of dielectric layers, and
wherein a dielectric constant of the plurality of dielectric layers increases toward an upper surface of the substrate.

12. The semiconductor device of claim 1, wherein the first electrode structure and the second electrode structure are on substantially a same level as a level of the circuit interconnection structure.

13. The semiconductor device of claim 1, further comprising:
a third electrode structure extending in the first direction and stacked in the first direction on the impurity regions;
a fourth electrode structure extending in the first direction and stacked in the first direction on the circuit devices; and
a second insulating structure between the third electrode structure and the fourth electrode structure.

14. The semiconductor device of claim 1, further comprising:
a lower bonding structure connected to the circuit interconnection structure and an upper bonding structure connected to the lower bonding structure,
wherein the lower bonding structure includes a lower bonding via connected to the circuit interconnection structure and a lower bonding pad connected to the lower bonding via,
wherein the upper bonding structure includes an upper bonding via connected to the upper interconnection structure and an upper bonding pad connected to the upper bonding via, and
wherein the lower bonding pad and the upper bonding pad are bonded to each other.

15. A semiconductor device, comprising:
a substrate including an active region;
circuit devices on the active region;
a device isolation region defining the active region;
impurity regions in the active region on first and second sides of the circuit devices;
a first electrode structure on the device isolation region, vertically overlapping the device isolation region, and extending in a first direction that is perpendicular to an upper surface of the substrate;
a second electrode structure on the device isolation region, vertically overlapping the device isolation region, and spaced apart from the first electrode structure in a second direction perpendicular to the first direction; and
an insulating structure between the first electrode structure and the second electrode structure,
wherein each of the first electrode structure and the second electrode structure extends in a third direction perpendicular to the first direction and the second direction and has a plate shape.

16. The semiconductor device of claim 15, wherein at least a portion of the first electrode structure and the second electrode structure extends at least into a portion of the device isolation region.

17. The semiconductor device of claim 15, further comprising:
dummy patterns spaced apart from each other in the second direction and the third direction and between the circuit devices,
wherein at least a portion of the first electrode structure and the second electrode structure vertically overlap the dummy patterns.

18. The semiconductor device of claim 15, further comprising:
a stopper layer on a portion of a surface of the substrate along the surface of the substrate in the device isolation region,
wherein at least a portion of the first electrode structure and the second electrode structure is in contact with the stopper layer.

19. A data storage system, comprising:
a semiconductor storage device including a substrate, an active region in the substrate, circuit devices on the substrate, a device isolation region defining the active region, an interconnection structure electrically connected to the circuit devices, a capacitor structure on the device isolation region and vertically overlapping the device isolation region, memory cells, and input/output pad; and
a controller electrically connected to the semiconductor storage device through the input/output pad and configured to control the semiconductor storage device,
wherein the capacitor structure includes:
a first electrode structure extending in a first direction perpendicular to an upper surface of the substrate and including first capacitor electrodes stacked in the first direction, a second electrode structure including second capacitor electrodes stacked in the first direction, and first insulating structure between the first electrode structure and the second electrode structure,
wherein the first capacitor electrodes and the second capacitor electrodes are spaced apart from each other and arranged alternately in the second direction parallel to an upper surface of the substrate, extend in a third direction perpendicular to the first direction and the second direction, and
wherein each of the first capacitor electrodes and the second capacitor electrodes has a plate shape.

20. The data storage system of claim 19, wherein the first electrode structure and the second electrode structure are electrically isolated from the circuit devices.
